(19) United States
(12) Patent Application Publication
(10) Pub. No.: US 2026/0040828 A1
(43) Pub. Date: Feb. 5, 2026

(54) CRYSTAL UNIT WITH BUILT-IN TEMPERATURE SENSOR

(71) Applicant: NIHON DEMPA KOGYO CO., LTD., Tokyo (JP)

(72) Inventor: Shuichi MIZUSAWA, Saitama (JP)

(73) Assignee: NIHON DEMPA KOGYO CO., LTD., Tokyo (JP)

(21) Appl. No.: 19/230,113

(22) Filed: Jun. 6, 2025

(30) Foreign Application Priority Data
Jul. 31, 2024 (JP) 2024-124115

(51) Int. Cl. H10N 30/80; G01K 1/14; G01K 13/04; H10N 30/88

(52) U.S. Cl. CPC H10N 30/802; G01K 1/14; G01K 13/04; H10N 30/88

(57) ABSTRACT

A crystal unit with a built-in temperature sensor includes a container, a quartz-crystal vibrating piece and a temperature sensor, a lid member, and a pedestal. The quartz-crystal vibrating piece and the temperature sensor are mounted in the container. The temperature sensor is provided on a first principal surface of the container. The lid member is connected to the container and sealing the quartz-crystal vibrating piece and the temperature sensor. The pedestal made of crystal has a height higher than a height of the temperature sensor disposed in a region of the first principal surface other than a region where the temperature sensor is provided. The quartz-crystal vibrating piece has a portion above the temperature sensor and another portion connected and secured to the pedestal made of crystal.

### CROSS-REFERENCE TO RELATED APPLICATIONS

This application is based on and claims priority under 35 U.S.C. § 119 to Japanese Patent Application No. 2024-124115, filed on Jul. 31, 2024, the entire content of which is incorporated herein by reference.

### TECHNICAL FIELD

This disclosure relates to a crystal unit including a built-in temperature sensor, such as a thermistor.

### DESCRIPTION OF THE RELATED ART

A so-called crystal unit with a built-in temperature sensor, which incorporates an AT-cut quartz-crystal vibrating piece and a temperature sensor in a single container, has come to be widely used in recent years. This is because an external electronic device (a chipset), which is designed on an assumption of use with this crystal unit, compensates an oscillation frequency of the quartz-crystal vibrating piece, based on temperature information detected by the above-described temperature sensor, thereby allowing the target frequency to be obtained with higher accuracy.

Typical examples of the crystal unit with the built-in temperature sensor include a single-chamber-structure one and an H-shaped-structure one. The former has a quartz-crystal vibrating piece and a temperature sensor mounted and airtightly sealed within one chamber (for example, Paragraph 75 or FIG. 7 in Japanese Unexamined Patent Application Publication No. 2023-70552 and the like). The latter has a first chamber in which a quartz-crystal vibrating piece is mounted and a second chamber in which a temperature sensor is mounted in which the first chamber and the second chamber are stacked back to back, and the first chamber is airtightly sealed (for example, ABSTRACT or FIG. 1 in Japanese Unexamined Patent Application Publication No. 2022-140662 and the like).

The single-chamber-structure one is easier to improve a temperature compensation accuracy compared with an H-shaped-structure one because the quartz-crystal vibrating piece and the temperature sensor are mounted within the same space, thus leading to a similar heat influence to the quartz-crystal vibrating piece and the temperature sensor.

Further miniaturization is also required for the single-chamber-structure one. To meet the requirement, the quartz-crystal vibrating piece and the temperature sensor are disposed in a three-dimensionally in a vertical direction to decrease footprint. For example, the crystal unit as disclosed in FIG. 7 in Japanese Unexamined Patent Application Publication No. 2023-70552 has the structure having a depressed portion for exclusively mounting a temperature sensor in a container of the crystal unit, mounting a temperature sensor within the depressed portion and disposing the quartz-crystal vibrating piece thereabove. This container having the depressed portion for a temperature sensor is constituted of a ceramic package (such as Paragraph 75 in Japanese Unexamined Patent Application Publication No. 2023-70552).

On the other hand, further improvement in frequency accuracy is desired for a crystal unit with a built-in temperature sensor. Thus, it is desired to achieve both miniaturization and improved frequency accuracy.

A need thus exists for a crystal unit with a built-in temperature sensor which is not susceptible to the drawback mentioned above.

### SUMMARY

According to an aspect of this disclosure, there is provided a crystal unit with a built-in temperature sensor. The crystal unit includes a container, a quartz-crystal vibrating piece and a temperature sensor, a lid member, and a pedestal. The quartz-crystal vibrating piece and the temperature sensor are mounted in the container. The temperature sensor is provided on a first principal surface of the container. The lid member is connected to the container and sealing the quartz-crystal vibrating piece and the temperature sensor. The pedestal made of crystal has a height higher than a height of the temperature sensor disposed in a region of the first principal surface other than a region where the temperature sensor is provided. The quartz-crystal vibrating piece has a portion above the temperature sensor and another portion connected and secured to the pedestal made of crystal.

### BRIEF DESCRIPTION OF THE DRAWINGS

The foregoing and additional features and characteristics of this disclosure will become more apparent from the following detailed description considered with reference to the accompanying drawings, wherein:

FIG. 1A to FIG. 1C are drawings for describing a crystal unit 10 with a built-in temperature sensor according to a first embodiment;

FIG. 2A to FIG. 2C are drawings for describing a crystal unit 30 with a built-in temperature sensor according to a second embodiment;

FIG. 3A and FIG. 3B are drawings for describing a preferable combination of a quartz-crystal vibrating piece and a pedestal made of crystal; and

FIG. 4 is a drawing for describing another example of a container used in this disclosure.

### DETAILED DESCRIPTION

The following describes embodiments of a crystal unit with a built-in temperature sensor according to this disclosure with reference to the drawings. Each drawing used in the description is merely illustrated schematically for understanding this disclosure. In each drawing used in the description, the same reference numeral is attached to a similar component, and its description is omitted in some cases. Material structures, numerical examples and the like described in the following description are merely preferable examples within the scope of this disclosure. Therefore, this disclosure is not limited to only the following embodiments.

### 1. First Embodiment

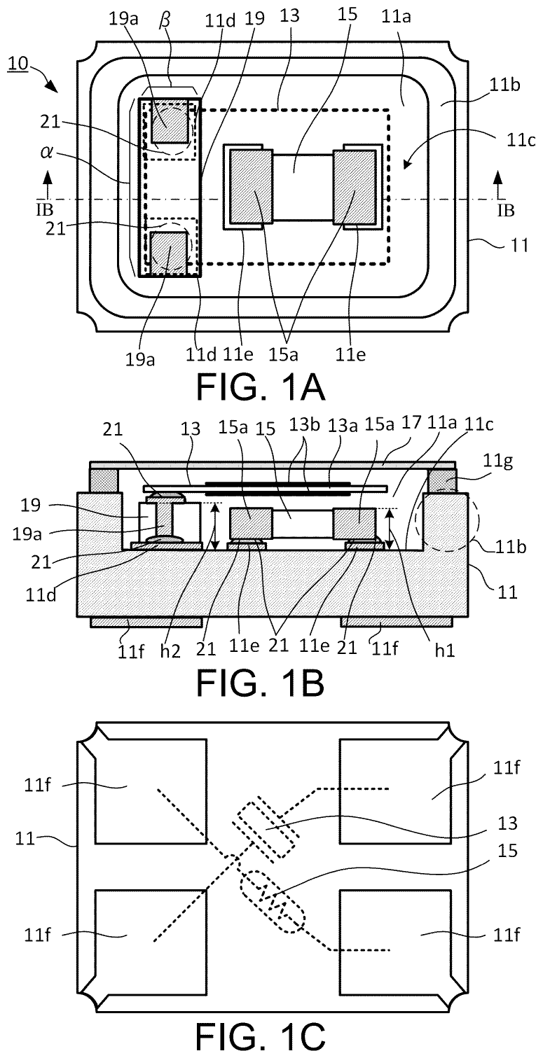

FIG. 1A to FIG. 1C are drawings for describing a crystal unit 10 with a built-in temperature sensor (hereinafter sometimes referred to as the crystal unit 10 for short) in a first embodiment. In particular, FIG. 1A is a plan view thereof, FIG. 1B is a sectional drawing taken along the line IB-IB in FIG. 1A, and FIG. 1C is a bottom view. It should be noted that FIG. 1A illustrates a state where a lid member 17 illustrated in FIG. 1B is removed.

The crystal unit 10 includes a container 11, a quartz-crystal vibrating piece 13 and a temperature sensor 15 mounted in the container 11, the lid member 17 connected to the container 11 and sealing the quartz-crystal vibrating piece 13 and the temperature sensor 15, and a pedestal 19 made of crystal, which is one of the features in the disclosure. The following specifically describes respective components.

In the case of this embodiment, the container 11 includes a depressed portion 11a, which contains the quartz-crystal vibrating piece 13 and the temperature sensor 15, and a dike 11b constituting the depressed portion 11a. In this first embodiment, a bottom surface of the depressed portion 11a corresponds to a first principal surface 11c of the container 11 in the disclosure. Each of the container 11 and the depressed portion 11a has an approximately rectangular shape in plan view.

Also, the container 11 includes two first pads 11d, along a direction parallel to short sides of the depressed portion 11a, for mounting the pedestal 19 made of crystal in a region of the bottom surface of the depressed portion 11a, that is, on the first principal surface, and the region is close to one short side of the depressed portion 11a. Furthermore, the container 11 includes two second pads 11e for mounting the temperature sensor 15 in a region apart from the first pads 11d on the bottom surface of the depressed portion 11a. In this case, an arranging direction of the first pads 11d is perpendicular to an arranging direction of the second pads 11e.

Also, external connecting terminals 11f for connecting an external electronic device (not illustrated) are disposed on an outer bottom surface of the container 11, for example, in proximities of four corners of the bottom surface. The first pads 11d, the second pads 11e, and the external connecting terminals 11f are connected with a predetermined relationship, through arbitrary wiring such as via-wiring or castellation wiring (not illustrated).

In this case, the container 11 is constituted of a ceramic package. However, while the conventional ceramic packages disclosed in Japanese Unexamined Patent Application Publication No. 2023-70552 need to have a depressed portion for exclusively incorporating a temperature sensor, in the case of the package according to the disclosure, the depressed portion for exclusively incorporating a temperature sensor can be eliminated since a mounting space in the vertical direction for incorporating a temperature sensor can be secured with the pedestal 19 made of crystal, which has a predetermined height. Therefore, the cost reduction of ceramic packages can be easily achieved. Since it is not necessary to provide a dedicated depressed portion for incorporating a temperature sensor, an area for mounting the temperature sensor can be increased.

The quartz-crystal vibrating piece 13, in this case, is an AT-cut quartz-crystal vibrating piece including an AT-cut crystal element 13a and excitation electrodes 13b disposed on the front and back of the AT-cut crystal element 13a, and has a rectangular shape in plan view. The mounted position and the like of the quartz-crystal vibrating piece 13 will be described later.

The temperature sensor 15 has a height h1 (see FIG. 1B). The temperature sensor 15, in the case of this embodiment, is constituted of a thermistor with a rectangular solid shape. The temperature sensor 15 has connecting terminals 15a on both the ends in the longitudinal direction, and the connecting terminals 15a are connected to the second pads 11e on the bottom surface of the depressed portion 11a of the container 11 via conductive adhesives 21. Note that the height h1 of the temperature sensor 15 is a height after mounting the temperature sensor 15 in the container 11. This height h1 will be described again when the pedestal 19 made of crystal is described later because a relationship between the height h1 and a height h2 of the pedestal 19 made of crystal, described later, is important.

The lid member 17 seals, typically seals airtightly, the quartz-crystal vibrating piece 13, the temperature sensor 15, and the pedestal 19 made of crystal in cooperation with the container 11. The lid member 17 can be any member corresponding to the sealing method of the crystal unit 10. For example, as illustrated in FIG. 1B, when a seam sealing method is used for the sealing method, a seam ring 11g made of a metal is provided on a top surface of the dike 11b of the container 11 while the lid member 17 is a plate-shaped member constituted of a kovar material or the like, which is weldable to the seam ring 11g.

The pedestal 19 made of crystal has a height h2, which is higher than the height h1 of the temperature sensor 15 (h2>h1). The pedestal 19 made of crystal, in this embodiment, has a rectangular solid shape, and a long side dimension a (see FIG. 1A) is approximately equal to or longer than a short side of the quartz-crystal vibrating piece 13, and shorter than a short side of the depressed portion 11a of the container 11. Also, a short-side dimension B is set to an arbitrary length that does not come into contact with the temperature sensor 15, for example, to a length that does not reach the excitation electrode 13b. Note that the height h2 of the pedestal 19 made of crystal is the height after the pedestal 19 made of crystal is mounted onto the first principal surface 11c of the container 11. Thus, the top surface of the pedestal 19 made of crystal is positioned higher than the top surface of the temperature sensor 15.

How large a difference Δh (=h2−h1) between the height h2 of the crystal pedestal 19 and the height h1 of the temperature sensor 15 should be determined by taking into account factors such as avoiding contact between the quartz-crystal vibrating piece 13 and the temperature sensor 15, not exceeding a product height limit of the crystal unit 10, possible movement of an end portion of the quartz-crystal vibrating piece 13 due to external impacts, and variations in mounting of both the quartz-crystal vibrating piece 13 and the temperature sensor 15. The difference Δh is, for example, preferably 10 to 40 μm, more preferably 15 to 25 μm, and even more preferably 10 to 20 μm, although the value should not be limited thereto.

Also, the pedestal 19 made of crystal includes a wiring 19a constituted of a metal film and the like, across a top surface, a side surface and a bottom surface thereof, for example. The wiring 19a allows the quartz-crystal vibrating piece 13 and the first pads 11d of the container 11 to be electrically connected in cooperation with the conductive adhesive 21 described later.

The pedestal 19 made of crystal is mounted within the depressed portion 11a in a state close to one short side of the depressed portion 11a of the container 11 such that the long sides of the pedestal 19 are parallel to the short sides of the depressed portion 11a. The first pads 11d of the container 11 and a part of the bottom surface among the wiring 19a of the pedestal 19 are connected and secured via the conductive adhesives 21.

The quartz-crystal vibrating piece 13 has one portion above the temperature sensor 15 and another portion connected and secured to the pedestal 19 made of crystal with the conductive adhesives 21. Accordingly, the quartz-crystal vibrating piece 13 is connected and secured in a cantilevered manner to the top surface of the pedestal 19 made of crystal, in a positional relationship that substantially covers the temperature sensor 15 from above.

This crystal unit 10 can ensure a space for mounting the temperature sensor 15 three-dimensionally below the quartz-crystal vibrating piece 13 and reduce a stress effect against the quartz-crystal vibrating piece 13 since the predetermined pedestal 19 made of crystal is disposed in a predetermined location.

### 2. Second Embodiment

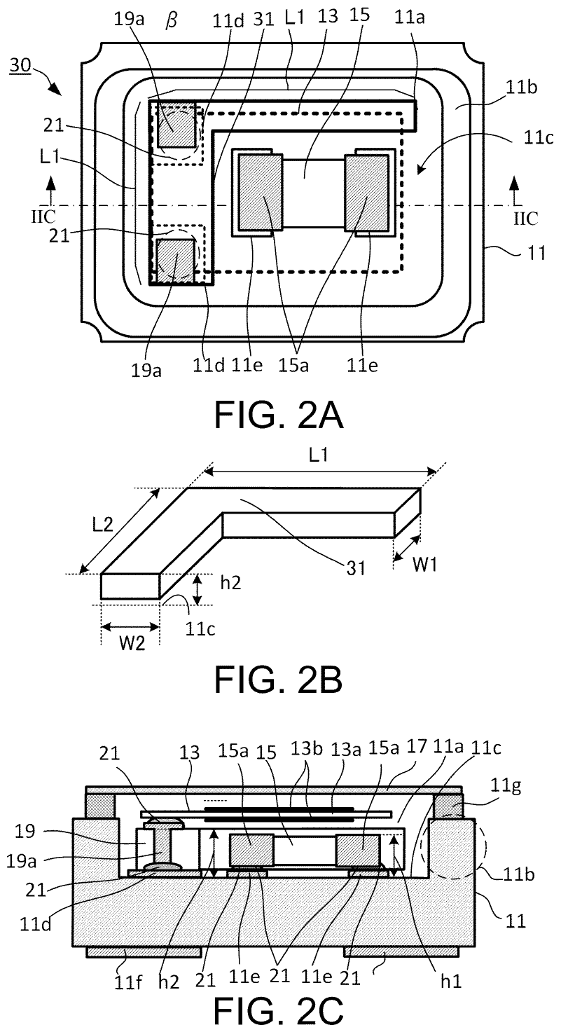

FIG. 2A to FIG. 2C are the drawings for describing a crystal unit 30 with a built-in temperature sensor (hereinafter sometimes referred to as the crystal unit 30 for short) according to a second embodiment. In particular, FIG. 2A is a plan view thereof, FIG. 2B is a perspective view of a pedestal 31 made of crystal according to the second embodiment, and FIG. 2C is a sectional drawing taken along the line IIC-IIC in FIG. 2A.

A difference between the crystal unit 30 in the second embodiment and the crystal unit 10 in the first embodiment lies in the planar shapes of the pedestals made of crystal.

As illustrated in FIG. 2, the pedestal 31 made of crystal included in the crystal unit 30 is constituted by a first linear portion L1, and a second linear portion L2 intersecting (perpendicular to the first linear portion L1 in this example) and connected with the first linear portion L1. The pedestal 31 has an L-shape in plan view and has a height h1. This height h1 is a height after being mounted in the container, similarly to the first embodiment.

In the pedestal 31 made of crystal, the dimensions of the first linear portion L1 and the second linear portion L2 of the L-shape are selected such that the pedestal 31 made of crystal does not contact the temperature sensor 15. Moreover, when the quartz-crystal vibrating piece 13 has a rectangular shape in plan view, a length of the first linear portion L1 is equal to or more than a half of a length of a long side of the quartz-crystal vibrating piece 13, and in the case of the example in FIG. 2, the length of the first linear portion L1 is equal to or more than the length of the long side of the quartz-crystal vibrating piece 13. A width W1 of the first linear portion L1 has a dimension such that this pedestal 31 is dimensioned to extend below the quartz-crystal vibrating piece 13 within a range in which the pedestal 31 does not contact the temperature sensor 15. Also, the second linear portion L2 of the pedestal 31 has a length that is longer than a short side of the quartz-crystal vibrating piece 13, and the length does not allow the pedestal 31 to contact the container 11. A width W2 of the second linear portion L2 of the pedestal 31 has a length that allows the pedestal 31 to support the quartz-crystal vibrating piece 13 in a cantilevered manner without contacting the temperature sensor 15.

Also in the case of the crystal unit 30 of this second embodiment, since the crystal unit 30 includes the predetermined pedestal 31 made of crystal, it is possible to secure a space for mounting the temperature sensor 15 three-dimensionally below the quartz-crystal vibrating piece 13 and reduce a stress effect on the quartz-crystal vibrating piece 13, similarly to the case of the first embodiment. Furthermore, in the case of this crystal unit 30, since the first linear portion L1 of the L-shape is positioned under the quartz-crystal vibrating piece 13, even when the end portion of the quartz-crystal vibrating piece 13 droops, the first linear portion L1 of the pedestal 31 can suppress the end portion from drooping furthermore.

### 3. Relationship between Quartz-crystal Vibrating Piece and Pedestal Made of Crystal

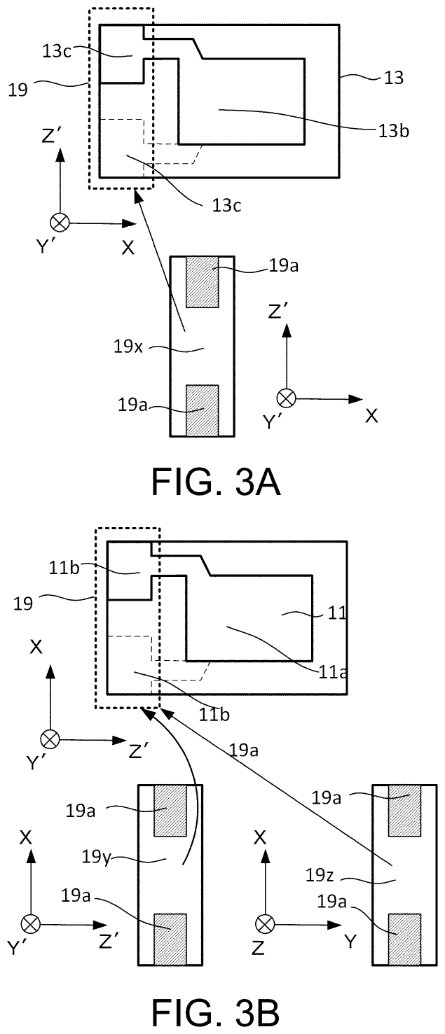

Next, with reference to FIG. 3A and FIG. 3B, a preferred combination of the quartz-crystal vibrating piece and the pedestal made of crystal will be described.

FIG. 3A is a plan view for illustrating the case where the AT-cut quartz-crystal vibrating piece 13 is secured to the crystal pedestal 19 at two points, and the two points are arranged along a Z′ axis of the crystal. Here, the Z′-axis means an axis displaced from the Z-axis of the crystal, which results from the cut angle of the AT-cut.

In the case of FIG. 3A, a pedestal 19x made of crystal is preferably a pedestal made of a crystal AT-cut plate and disposed in the same axial direction as an axial direction of the quartz-crystal vibrating piece 13. That is, the quartz-crystal vibrating piece 13 and the pedestal 19x made of crystal are preferably disposed such that the X-axis, the Y′-axis, and the Z′-axis of crystal of the quartz-crystal vibrating piece 13 are aligned with the X-axis, the Y′-axis, the Z′-axis of crystal of the pedestal 19x made of crystal. It should be noted that the term “the axes are aligned” does not preclude slight deviations in the cutting angle within a range classified as an AT-cut, for example, deviations of several minutes are acceptable.

FIG. 3B is a plan view for illustrating the case where the AT-cut quartz-crystal vibrating piece 13 is secured to the crystal pedestal 19 at two points, and the two points are arranged along the X-axis of the crystal.

In this case of FIG. 3B, preferred examples of the pedestal 19 made of crystal includes two types of pedestals. A first pedestal 19y made of crystal is a pedestal made of a crystal AT-cut plate. Note that, in the case of the pedestal 19y made of crystal, a longitudinal direction of the pedestal 19y made of crystal is along the X-axis of the crystal and a short side direction of the pedestal 19y is along the Z′-axis of the crystal.

Meanwhile, a second pedestal 19z made of crystal is a pedestal made of a crystal Z-plate. In this case, the pedestal 19z is disposed such that a direction along the X-axis of the crystal of the pedestal made of a crystal Z-plate is along the X-axis of the quartz-crystal vibrating piece 13.

The case where a crystal axis of the crystal of the quartz-crystal vibrating piece 13 is aligned with a crystal axis of the pedestal 19 made of crystal is preferred compared with the case not aligned therewith because the effect for reducing a stress brought by the pedestal made of crystal is heightened.

While some embodiments of the disclosure are described above, this disclosure is not limited to the above-described embodiments.

For example, in the above-embodiments, containers made of ceramic are exemplified as the container 11 but it may be containers made of crystal and the like. Specifically, a container made of crystal having a configuration in which one or a plurality of blanks are bonded by intermetallic bonding with a predetermined wiring, and a container made of crystal having a configuration in which one or a plurality of blanks are bonded with a ring-shaped blank constituting a dike by intermetallic bonding with a predetermined wiring is disposed can be each applied to by this disclosure, for example. Specifically, for example, a temperature sensor or the pedestal made of crystal according to the disclosure may be mounted to the containers disclosed in FIG. 1 or FIG. 2 and the like in Japanese Unexamined Patent Application Publication No. 2022-145456 related to this applicant.

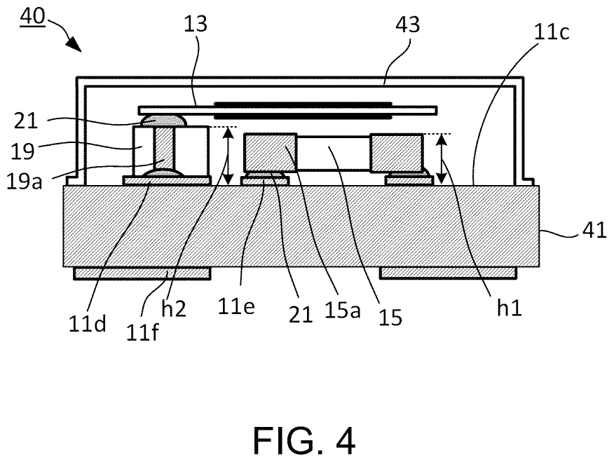

As shown in FIG. 4, this disclosure can also apply to a crystal unit 40 with a built-in temperature sensor, which configures a sealing space with a container 41 with a flat plate shape (a base plate 41) and a cap-shaped lid member 43 covering the quartz-crystal vibrating piece 13 and the like with a depressed portion, using the pedestal made of crystal.

When implementing the disclosure, the pedestal made of crystal may be a rectangular parallelepiped. In recent years, many of the quartz-crystal vibrating piece that are mass-produced are rectangular in shape when viewed from above, and they are often secured to a container at two points along one of their short sides. In such cases, a pedestal made of crystal in a rectangular parallelepiped has an advantage of being able to be placed in a position that does not come into contact with the temperature sensor, and is easy to place in a position close to one of short sides of the rectangular-shaped quartz-crystal vibrating piece in plan view. The quartz-crystal vibrating piece can then be supported in a cantilevered state without coming into contact with the temperature sensor.

When implementing the disclosure, the pedestal made of crystal may be preferably a pedestal in an L-shape in plan view including a first linear portion and a second linear portion intersecting and connected with the first linear portion. However, as described above with reference to FIG. 2A to FIG. 2C, the first linear portion and the second linear portion may be set with a predetermined width and a predetermined length in consideration of the relationship with the temperature sensor and the quartz-crystal vibrating piece. Specifically, in the case where the quartz-crystal vibrating piece may have a rectangular shape in plan view, the length of the first linear portion may be equal to or longer than the length of a half of the long side of the quartz-crystal vibrating piece in the rectangular shape, may be preferably equal to or longer than the length of the long side of the quartz-crystal vibrating piece, and the width of the first linear portion may be a width that does not allow contact of the temperature sensor. On the other hand, the length of the second linear portion may be approximately equal to or longer than the length of the short side of the quartz-crystal vibrating piece in the rectangular shape and does not allow contact of the container, and the width of the second linear portion may be a width that does not allow contact of the temperature sensor and allows the cantilever support of the quartz-crystal vibrating piece. These will result in that the quartz-crystal vibrating piece can be connected and secured to the second linear portion of the pedestal made of crystal in the L-shape and the first linear portion of the pedestal made of crystal in the L-shape can function as a stopper suppressing the end portion of the quartz-crystal vibrating piece from drooping. In addition, the pedestal in the L-shape can be stably mounted in a first principal surface of the container since the pedestal does not fall.

When implementing the disclosure, the container can be selected from containers made of ceramic, glass, crystal, resin (glass epoxy) or metal and the like. Particularly, a container made of ceramic may be a container used in the disclosure because of the excellent results of the mass production. In the case where a container made of ceramic is used, in the case of this disclosure, the difference in a thermal expansion coefficient between ceramic and crystal can be reduced since the pedestal made of crystal is present between the ceramic and the quartz-crystal vibrating piece in this disclosure. Moreover, the space for mounting the temperature sensor can be secured by the pedestal itself made of crystal having a height higher than a height of the temperature sensor, leading to the cost reduction of the container made of ceramic since the container made of ceramic alone needs to have a simple structure without a depressed portion for the temperature sensor.

Also, the container may be a container made of crystal constituted of a plurality of blanks by intermetallic bonding. For example, the container may be the container made of crystal and the like described in Japanese Unexamined Patent Application Publication No. 2021-179882 related to this applicant. In the case where the container may be the container made of crystal, a crystal unit with a built-in temperature sensor in which a container and a pedestal are each made of crystal, that is, totally crystal, can be achieved. Furthermore, when the container is a container made of crystal, a crystal unit with a built-in temperature sensor, which has a thin thickness and a high accuracy, can be achieved, since crystal can be processed by polishing for the required thickness and with high accuracy.

A crystal unit with a built-in temperature sensor according to this disclosure includes the pedestal made of crystal having the height higher than the height of the temperature sensor in the region other than the region where the temperature sensor is disposed on the first principal surface of the container. Accordingly, the pedestal made of crystal acts as a spacer member securing the space in the height direction when mounting the temperature sensor on the container and acts as a stress-reducing member reducing the stress, which results from the difference in the thermal expansion coefficient between the container and the quartz-crystal vibrating piece and/or the effect of the adhesives and the like for adhering the container to the quartz-crystal vibrating piece.

Therefore, according to this disclosure, an improvement in the frequency accuracy by the miniaturization of footprint of the crystal unit obtained from a three-dimensionally disposing the temperature sensor and the quartz-crystal vibrating piece in the vertical direction and the reduction of the stress and the like brought to the quartz-crystal vibrating piece can be achieved.

Accordingly, the miniaturization can be achieved, and a crystal unit with a built-in temperature sensor having the novel structure that can further improve the frequency accuracy compared with the conventional ones can be provided.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A crystal unit with a built-in temperature sensor, comprising:
a container;
a quartz-crystal vibrating piece and a temperature sensor mounted in the container, the temperature sensor being provided on a first principal surface of the container;
a lid member connected to the container and sealing the quartz-crystal vibrating piece and the temperature sensor; and
a pedestal made of crystal having a height higher than a height of the temperature sensor disposed in a region of the first principal surface other than a region where the temperature sensor is provided, wherein
the quartz-crystal vibrating piece has a portion above the temperature sensor and another portion connected and secured to the pedestal made of crystal.

2. The crystal unit with the built-in temperature sensor according to claim 1, wherein
the container has a rectangular shape in plan view and a depressed portion, and the depressed portion has a rectangular shape in plan view and houses the quartz-crystal vibrating piece and the temperature sensor,
the pedestal made of crystal is a rectangular parallelepiped and mounted in the depressed portion such that a long side of the rectangular parallelepiped becomes parallel to one short side of the depressed portion at a proximity of the one short side,
the quartz-crystal vibrating piece has a rectangular shape in plan view and has one short side connected and secured to the pedestal made of crystal by cantilever support, and
the temperature sensor is mounted below the quartz-crystal vibrating piece.

3. The crystal unit with the built-in temperature sensor according to claim 1, wherein
the container has a rectangular shape in plan view and a depressed portion, and the depressed portion has a rectangular shape in plan view and houses the quartz-crystal vibrating piece and the temperature sensor,
the pedestal made of crystal is a pedestal in an L-shape in plan view including a first linear portion and a second linear portion intersecting and connected with the first linear portion and is the pedestal in the L-shape in plan view having a shape in which the first linear portion extends below the quartz-crystal vibrating piece without contacting the temperature sensor, and
the quartz-crystal vibrating piece has a rectangular shape in plan view and has one short side connected and secured to the second linear portion of the pedestal made of crystal by cantilever support.

4. The crystal unit with the built-in temperature sensor according to claim 1, wherein
when the height of the temperature sensor is h1, the height of the pedestal made of crystal is h2, and a difference between the two is Δh=h2−h1, Δt is 10 to 40 μm.

5. The crystal unit with the built-in temperature sensor according to claim 1, wherein
the quartz-crystal vibrating piece is an AT-cut quartz-crystal vibrating piece,
the pedestal made of crystal is an AT-cut crystal piece or a Z-cut crystal piece,
the quartz-crystal vibrating piece and the pedestal made of crystal are mounted in the container with at least part of respective crystal axes of the quartz-crystal vibrating piece and the pedestal made of crystal aligned.

6. The crystal unit with the built-in temperature sensor according to claim 1, wherein
the quartz-crystal vibrating piece is an AT-cut quartz-crystal vibrating piece having a rectangular shape in plan view,
the pedestal made of crystal is an AT-cut crystal piece or a Z-cut crystal piece, the quartz-crystal vibrating piece has one short side connected and secured to the pedestal made of crystal,
the quartz-crystal vibrating piece and the pedestal made of crystal are mounted in the container with the crystal axes of the quartz-crystal vibrating piece and the pedestal made of crystal aligned in a direction along the one short side.

7. The crystal unit with the built-in temperature sensor according to claim 1, wherein
the container is a container made of ceramic.

8. The crystal unit with the built-in temperature sensor according to claim 1, wherein
the container is a container made of ceramic and has one depressed portion housing the quartz-crystal vibrating piece and the temperature sensor.
